(19) United States
(12) Patent Application Publication
(10) Pub. No.: US 2020/0118989 A1
(43) Pub. Date: Apr. 16, 2020

(54) LIGHT EMITTING DEVICE PACKAGE STRUCTURE AND MANUFACTURING METHOD THEREOF

(71) Applicant: Unimicron Technology Corp., Taoyuan (TW)

(72) Inventors: Pei-Wei WANG, Taipei City (TW); Cheng-Ta KO, Taoyuan (TW); De-Shiang LIU, Taoyuan City (TW); Yu-Hua CHEN, Hsinchu City (TW)

(21) Appl. No.: 16/205,245

(22) Filed: Nov. 30, 2018

(30) Foreign Application Priority Data
Oct. 12, 2018 (TW) 107136079

(51) Int. Cl. H01L 25/16; H01L 33/62; H01L 33/54; H01L 23/538; H01L 25/075; H01L 21/48; H01L 23/00

(52) U.S. Cl. CPC H01L 25/167; H01L 33/62; H01L 33/54; H01L 23/5383; H01L 23/5386; H01L 25/0753; H01L 2924/1426; H01L 24/81; H01L 2933/0066; H01L 2933/005; H01L 24/16; H01L 2224/16227; H01L 2924/12041; H01L 21/4857

(57) ABSTRACT

A light emitting device package structure includes: a substrate structure including a substrate and a first circuit layer, the substrate having a first surface, the first circuit layer over the first surface; a chip over the substrate structure and electrically connected to the first circuit layer; a conductive connector over the substrate structure and electrically connected to the first circuit layer; a redistribution structure over the conductive connector, the redistribution structure including a first redistribution layer and a second redistribution layer over the first redistribution layer, the first redistribution layer including a second circuit layer electrically connected to the first circuit layer and a conductive contact in contact with the second circuit layer, the second redistribution layer including a third circuit layer in contact with the conductive contact; and a light emitting device over the redistribution structure and electrically connected to the third circuit layer.

### CROSS-REFERENCE TO RELATED APPLICATION

This application claims priority to Taiwan Application Serial Number 107136079, filed Oct. 12, 2018, which is herein incorporated by reference.

### BACKGROUND

### Field of Invention

The present disclosure relates to a light emitting device package structure and a method of manufacturing a light emitting device package structure.

### Description of Related Art

Conventionally, a driver chip is disposed in a frame region of a display device such as a mobile phone, a tablet, or the like. However, this design makes it necessary for the display device to have a sufficient area of the frame region, and a display region of the display device is thus reduced. In recent years, in order to realize a narrow frame of the display device, a chip-on-film (COF) technology is employed, that is, a portion of a flexible circuit board (FPC) is connected to a front surface of a substrate of the display device, and another portion of the flexible circuit board is bent to a back surface of the substrate. The required area of the frame region may be reduced by arranging the driver chip over the back surface of the flexible circuit board.

However, the above-mentioned bending causes stress to concentrate on a portion where the flexible circuit board is in contact with the substrate, which causes the portion to easily peel off or break, and wires on the flexible circuit board are also prone to break and the like. In addition, in order to connect the flexible circuit board to the substrate of the display device, it is still necessary to reserve a portion of the substrate to which the flexible circuit board is connected. Therefore, the frame region of the display device cannot be effectively reduced.

It may be seen from the above that the above existing methods obviously have inconveniences and defects, and need to be improved. In order to solve the above problems, the relevant fields have tried their best to find a solution, but for a long time, no suitable solution has been developed.

### SUMMARY

An aspect of the present disclosure provides a light emitting device package structure, which includes a substrate structure, a chip, a conductive connector, a redistribution structure, and a light emitting device. The substrate structure includes a substrate and a first circuit layer. The substrate has a first surface, and the first circuit layer is disposed over the first surface. The chip is disposed over the substrate structure and electrically connected to the first circuit layer. The conductive connector is disposed over the substrate structure and electrically connected to the first circuit layer. The redistribution structure is disposed over the conductive connector. The redistribution structure includes a first redistribution layer and a second redistribution layer disposed over the first redistribution layer. The first redistribution layer includes a second circuit layer electrically connected to the first circuit layer and a conductive contact in contact with the second circuit layer. The second redistribution layer includes a third circuit layer in contact with the conductive contact. The light emitting device is disposed over the redistribution structure and electrically connected to the third circuit layer.

According to some embodiments of the present disclosure, the light emitting device package structure further includes a protective carrier disclosed over the light emitting device.

According to some embodiments of the present disclosure, the light emitting device package structure further includes a protective layer covering the light emitting device and the second redistribution layer and filled between the light emitting device and the second redistribution layer.

Another aspect of the present disclosure provides a light emitting device package structure, which includes a substrate structure, a chip, a conductive connector, a redistribution structure, and a light emitting device. The substrate structure includes a substrate, a first circuit layer, a second circuit layer and a conductive through hole. The substrate has a first surface and a second surface opposite to the first surface. The first circuit layer is disposed over the first surface, and the second circuit layer is disposed over the second surface. The first circuit layer is electrically connected to the second circuit layer through the conductive through hole. The chip is disposed at a side of the second surface and electrically connected to the second circuit layer. The conductive connector is disposed over the substrate structure and electrically connected to the first circuit layer. The redistribution structure is disposed over the conductive connector. The redistribution structure includes a first redistribution layer and a second redistribution layer disposed over the first redistribution layer. The first redistribution layer includes a third circuit layer electrically connected to the first circuit layer and a conductive contact in contact with the third circuit layer. The second redistribution layer includes a fourth circuit layer in contact with the conductive contact. The light emitting device is disposed over the redistribution structure and electrically connected to the fourth circuit layer.

According to some embodiments of the present disclosure, the light emitting device package structure further includes a protective carrier disclosed over the light emitting device.

According to some embodiments of the present disclosure, the light emitting device package structure further includes a protective layer covering the light emitting device and the second redistribution layer and filled between the light emitting device and the second redistribution layer.

Another aspect of the present disclosure provides a method of manufacturing a light emitting device package structure, which includes: (i) providing a substrate structure, in which the substrate structure includes a first circuit layer; (ii) disposing a chip over the substrate structure, in which the chip is electrically connected to the first circuit layer; (iii) forming a redistribution structure over the substrate structure, in which the redistribution structure includes a first redistribution layer and a second redistribution layer disposed over the first redistribution layer, and the first redistribution layer includes a second circuit layer electrically connected to the first circuit layer through a conductive connector and a conductive contact in contact with the second circuit layer, and the second redistribution layer includes a third circuit layer in contact with the conductive contact; and (iv) disposing a light emitting device over the redistribution structure, in which the light emitting device is electrically connected to the third circuit layer.

According to some embodiments of the present disclosure, after the step (iv), the method further includes: (v) forming a protective carrier over the light emitting device; or (vi) forming a protective layer covering the light emitting device and the second redistribution layer and filled between the light emitting device and the second redistribution layer.

Another aspect of the present disclosure provides a method of manufacturing a light emitting device package structure, which includes: (a) providing a substrate structure, in which the substrate structure includes a first circuit layer, a second circuit layer and a conductive through hole, and the first circuit layer is electrically connected to the second circuit layer through the conductive through hole; (b) disposing a chip beneath the substrate structure, in which the chip is electrically connected to the second circuit layer; (c) forming a redistribution structure over the substrate structure, in which the redistribution structure includes a first redistribution layer and a second redistribution layer disposed over the first redistribution layer, and the first redistribution layer includes a third circuit layer electrically connected to the first circuit layer through a conductive connector and a conductive contact in contact with the third circuit layer, and the second redistribution layer includes a fourth circuit layer in contact with the conductive contact; and (d) disposing a light emitting device over the redistribution structure, in which the light emitting device is electrically connected to the fourth circuit layer.

According to some embodiments of the present disclosure, after the step (d), the method further includes: (e) forming a protective carrier over the light emitting device; or (f) forming a protective layer covering the light emitting device and the second redistribution layer and filled between the light emitting device and the second redistribution layer.

It is to be understood that both the foregoing general description and the following detailed description are by examples, and are intended to provide further explanation of the present disclosure as claimed.

### BRIEF DESCRIPTION OF THE DRAWINGS

The invention may be more fully understood by reading the following detailed description of the embodiment, with reference made to the accompanying drawings as follows:

FIG. 1 is a cross-sectional view of a light emitting device package structure according to a first embodiment of the present disclosure;

FIG. 2 is a cross-sectional view of a light emitting device package structure according to a second embodiment of the present disclosure;

FIG. 3 is a cross-sectional view of a light emitting device package structure according to a third embodiment of the present disclosure;

FIG. 4 is a cross-sectional view of a light emitting device package structure according to a fourth embodiment of the present disclosure;

FIGS. 5-6 are cross-sectional views showing stages of a method of forming a redistribution structure according to one embodiment of the present disclosure;

FIGS. 7-9 are cross-sectional views showing stages of a method of forming a light emitting device package structure according to one embodiment of the present disclosure;

FIG. 10 is a cross-sectional view showing a stage of a method of forming a light emitting device package structure according to one embodiment of the present disclosure;

FIG. 11 is a cross-sectional view showing a stage of a method of forming a light emitting device package structure according to one embodiment of the present disclosure;

FIGS. 12-13 are cross-sectional views showing stages of a method of forming a light emitting device package structure according to one embodiment of the present disclosure; and

FIG. 14 is a cross-sectional view showing a stage of a method of forming a light emitting device package structure according to one embodiment of the present disclosure.

### DETAILED DESCRIPTION

In order that the present disclosure is described in detail and completeness, implementation aspects and specific embodiments of the present disclosure with illustrative description are presented; but it is not the only form for implementation or use of the specific embodiments. The embodiments disclosed herein may be combined or substituted with each other in an advantageous manner, and other embodiments may be added to an embodiment without further description. In the following description, numerous specific details will be described in detail in order to enable the reader to fully understand the following embodiments. However, the embodiments of the present disclosure may be practiced without these specific details.

The embodiments of the present disclosure are described in detail below, but the present disclosure is not limited to the scope of the embodiments.

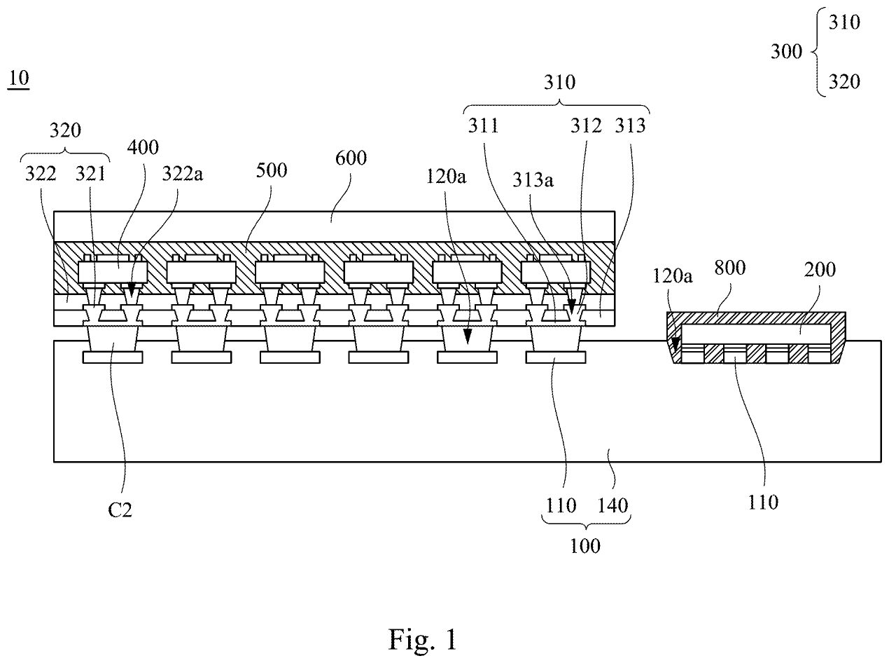

FIG. 1 is a cross-sectional view of a light emitting device package structure according to a first embodiment of the present disclosure. As shown in FIG. 1, the light emitting device package structure 10 includes a substrate structure 100, a chip 200, a conductive connector C2, a redistribution structure 300, and a light emitting device 400.

The substrate structure 100 includes a first circuit layer 110 and a substrate 140. The substrate 140 has a first surface, and the first circuit layer 110 is disposed over the first surface. The substrate 140 includes an opening 120a exposing a portion of the first circuit layer 110. In some embodiments, the substrate 140 is a rigid substrate, such as a glass substrate or a plastic substrate. In some embodiments, the first circuit layer 110 includes any electrically conductive material, such as a metal such as copper, nickel or silver. In some embodiments, the substrate structure 100 is a portion of a printed circuit board.

The chip 200 is disposed over the substrate structure 100 and electrically connected to the first circuit layer 110. Specifically, a lower surface of the chip 200 is provided with a plurality of metal bumps (e.g., chip pins), and the metal bumps are bonded to exposed portions of the first circuit layer 110 through a solder material or a conductive bonding material, so that the chip 200 is electrically connected to the first circuit layer 110. It should be understood that although the light emitting device package structure 10 illustrated in FIG. 1 includes only one chip 200, in other embodiments, the number of chips 200 may be more than one.

The conductive connector C2 is disposed over the substrate structure 100 and electrically connected to the first circuit layer 110. In some embodiments, the conductive connector C2 may be a solder ball or a metal pillar.

The redistribution structure 300 is disposed over the conductive connector C2, and the redistribution structure 300 includes a first redistribution layer 310 and a second redistribution layer 320.

The first redistribution layer 310 is disposed over the conductive connector C2. Specifically, the first redistribution layer 310 includes a second circuit layer 311, a conductive contact 312, and a first insulating layer 313. The second circuit layer 311 is electrically connected to the first circuit layer 110 through the conductive connector C2. In some embodiments, the second circuit layer 311 includes any electrically conductive material, such as a metal such as copper, nickel, or silver. In some embodiments, the second circuit layer 311 has a line width and a line spacing of less than 50 microns, such as 40 microns, 30 microns, 20 microns, 10 microns, 8 microns, 7 microns, 6 microns, 5 microns, 4 microns, 3 microns, 2 microns, 1 micron or 0.5 micron. The first insulating layer 313 covers the second circuit layer 311, and the first insulating layer 313 has a first through hole 313a. In some embodiments, the first insulating layer 313 includes a photosensitive dielectric material. The first through hole 313a exposes a portion of the second circuit layer 311, and the conductive contact 312 is filled in the first through hole 313a, so that the conductive contact 312 is in contact with the second circuit layer 311. The conductive contact 312 may be a metal pillar and the metal is, for example, a conductive metal such as copper, nickel or silver. As shown in FIG. 1, a width of the conductive contact 312 is gradually narrowed from top toward bottom, and has a trapezoidal shape with a wide top and a narrow bottom, but the shape of the conductive contact 312 is not limited thereto.

The second redistribution layer 320 is disposed over the first redistribution layer 310. Specifically, the second redistribution layer 320 includes a third circuit layer 321 and a second insulating layer 322. The third circuit layer 321 is in contact with the conductive contact 312. In some embodiments, the third circuit layer 321 includes any electrically conductive material, such as a metal such as copper, nickel, or silver. In some embodiments, the third circuit layer 321 has a line width and a line spacing of less than 50 microns, such as 40 microns, 30 microns, 20 microns, 10 microns, 8 microns, 7 microns, 6 microns, 5 microns, 4 microns, 3 microns, 2 microns, 1 micron or 0.5 micron. The second insulating layer 322 covers the third circuit layer 321, and the second insulating layer 322 has a second through hole 322a. Specifically, the second through hole 322a exposes a portion of the third circuit layer 321. In some embodiments, the second insulating layer 322 includes a photosensitive dielectric material.

The light emitting device 400 is disposed over the redistribution structure 300 and electrically connected to the third circuit layer 321. Specifically, a lower surface of the light emitting device 400 is provided with a plurality of metal bumps, and the metal bumps are bonded to exposed portions of the third circuit layer 321 through a solder material or a conductive bonding material filled in the second through hole 322a, so that the light emitting device 400 is electrically connected to the third circuit layer 321. In some embodiments, the light emitting device 400 includes a light emitting diode device. In some embodiments, the light emitting device 400 includes a miniature light emitting diode device. In some embodiments, the manner in which the light emitting element 400 is disposed over the redistribution structure 300 includes a pick and place mode or a mass transfer mode. In some embodiments, the solder material filled in the second through hole 322a includes SnBe, SnSb, or SAC alloy (i.e., an alloy of Sn, Ag, and Cu), but not limited thereto. In some other embodiments, the conductive bonding material filled in the second through hole 322a includes an anisotropic conductive film (ACF) or an anisotropic conductive paste (ACP), but not limited thereto.

As shown in FIG. 1, the light emitting device package structure 10 further includes a light transmissive adhesive layer 500, a protective carrier 600, and a chip protective layer 800. The light transmitting adhesive layer 500 covers the light emitting device 400 and the second insulating layer 322 and is filled between the light emitting device 400 and the second insulating layer 322. In some embodiments, the light transmissive adhesive layer 500 includes an optically clear adhesive (OCA). The protective carrier 600 is disposed over the light transmissive adhesive layer 500. In some embodiments, the protective carrier 600 is a rigid substrate, such as a glass substrate or a plastic substrate. The chip protective layer 800 covers the chip 200 and is filled in a gap between the chip 200 and the substrate 140. Therefore, the chip protective layer 800 can protect the bonding of the metal bumps of the chip 200 to the first circuit layer 110, thereby preventing occurrence of peeling. On the other hand, the chip protective layer 800 can also block moisture and avoid oxidation of the metal bumps, the solder material, and the first circuit layer 110. In some embodiments, the chip protective layer 800 includes a resin.

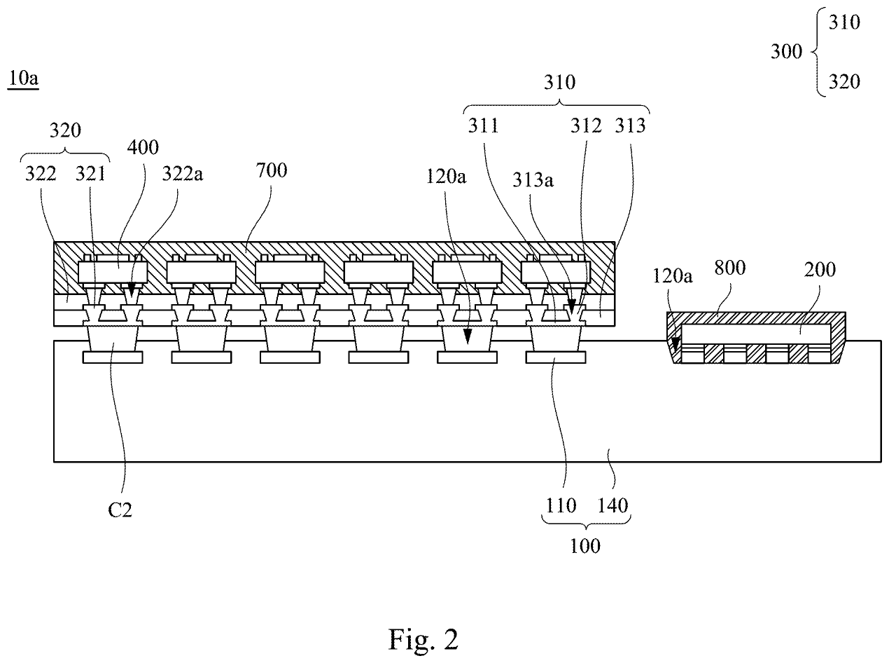

FIG. 2 is a cross-sectional view of a light emitting device package structure 10a according to a second embodiment of the present disclosure. The light emitting device package structure 10a of FIG. 2 is similar to that of FIG. 1, and the difference therebetween is that the protective layer 700 of FIG. 2 replaces the light transmissive adhesive layer 500 and the protective carrier 600 of FIG. 1. Specifically, the protective layer 700 covers the light emitting device 400 and the second insulating layer 322 and is filled between the light emitting device 400 and the second insulating layer 322. In some embodiments, the protective layer 700 includes a light transmissive resin. It is noted that as shown in FIG. 2, same or similar elements as those shown in FIG. 1 are given the same reference numerals, and the description thereof is omitted.

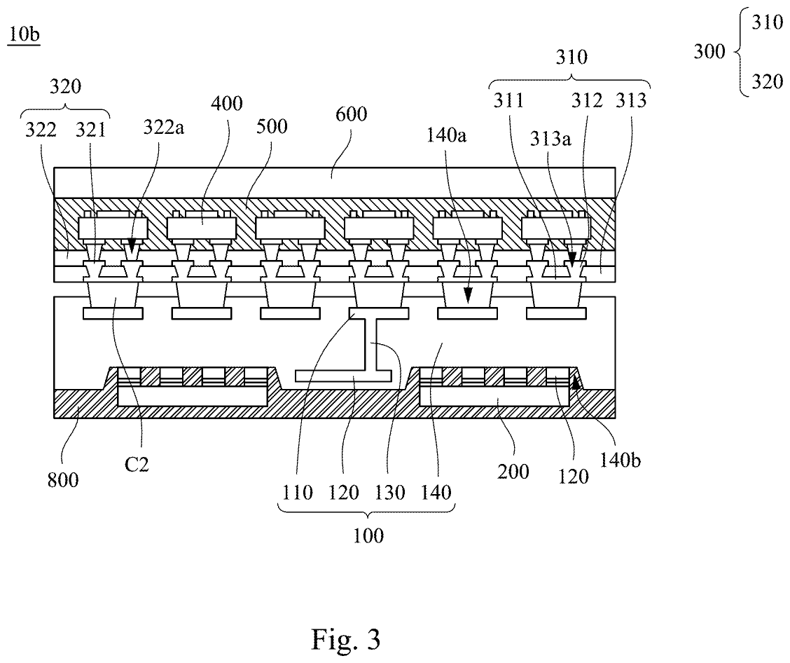

FIG. 3 is a cross-sectional view of a light emitting device package structure 10b according to a third embodiment of the present disclosure. As shown in FIG. 3, the light emitting device package structure 10b includes a substrate structure 100, a chip 200, a conductive connector C2, a redistribution structure 300, and a light emitting device 400.

The substrate structure 100 includes a first circuit layer 110, a second circuit layer 120, a conductive through hole 130, and a substrate 140. The substrate 140 has a first surface and a second surface opposite to the first surface. The first circuit layer 110 is disposed over the first surface of the substrate 140, and the second circuit layer 120 is disposed over the second surface of the substrate 140. The first circuit layer 110 is electrically connected to the second circuit layer 120 through the conductive through hole 130. The substrate 140 includes an opening 140a and an opening 140b. The opening 140a exposes a portion of the first circuit layer 110, and the opening 140b exposes a portion of the second circuit layer 120. In some embodiments, the first circuit layer 110, the second circuit layer 120, and the conductive through hole 130 include any conductive material, such as a metal such as copper, nickel, or silver. In some embodiments, the substrate structure 100 is a portion of a printed circuit board.

The chip 200 is disposed beneath the substrate structure 100 and electrically connected to the second circuit layer 120. Specifically, a surface of the chip 200 is provided with a plurality of metal bumps (e.g., chip pins), and the metal bumps are bonded to exposed portions of the second circuit layer 120 through a solder material or a conductive bonding material, so that the chip 200 is electrically connected to the second circuit layer 120. It should be understood that although the light emitting device package structure 10b illustrated in FIG. 3 includes two chips 200, in other embodiments, the number of chips 200 may be less than two or more than two.

The conductive connector C2 is disposed over the substrate structure 100 and electrically connected to the first circuit layer 110.

The redistribution structure 300 is disposed over the conductive connector C2, and the redistribution structure 300 includes a first redistribution layer 310 and a second redistribution layer 320.

The first redistribution layer 310 is disposed over the conductive connector C2. Specifically, the first redistribution layer 310 includes a third circuit layer 311, a conductive contact 312, and a first insulating layer 313. The third circuit layer 311 is electrically connected to the first circuit layer 110 through the conductive connector C2. In some embodiments, the third circuit layer 311 includes any electrically conductive material, such as a metal such as copper, nickel, or silver. In some embodiments, the third circuit layer 311 has a line width and a line spacing of less than 50 microns, such as 40 microns, 30 microns, 20 microns, 10 microns, 8 microns, 7 microns, 6 microns, 5 microns, 4 microns, 3 microns, 2 microns, 1 micron or 0.5 micron. The first insulating layer 313 covers the third circuit layer 311, and the first insulating layer 313 has a first through hole 313a. The first through hole 313a exposes a portion of the third circuit layer 311, and the conductive contact 312 is filled in the first through hole 313a, so that the conductive contact 312 is in contact with the third circuit layer 311. As shown in FIG. 3, a width of the conductive contact 312 is gradually narrowed from top toward bottom, and has a trapezoidal shape with a wide top and a narrow bottom, but the shape of the conductive contact 312 is not limited thereto.

The second redistribution layer 320 is disposed over the first redistribution layer 310. Specifically, the second redistribution layer 320 includes a fourth circuit layer 321 and a second insulating layer 322. The fourth circuit layer 321 is in contact with the conductive contact 312. In some embodiments, the fourth circuit layer 321 includes any electrically conductive material, such as a metal such as copper, nickel, or silver. In some embodiments, the fourth circuit layer 321 has a line width and a line spacing of less than 50 microns, such as 40 microns, 30 microns, 20 microns, 10 microns, 8 microns, 7 microns, 6 microns, 5 microns, 4 microns, 3 microns, 2 microns, 1 micron or 0.5 micron. The second insulating layer 322 covers the fourth circuit layer 321, and the second insulating layer 322 has a second through hole 322a. Specifically, the second through hole 322a exposes a portion of the fourth circuit layer 321.

The light emitting device 400 is disposed over the redistribution structure 300 and electrically connected to the fourth circuit layer 321. Specifically, a lower surface of the light emitting device 400 is provided with a plurality of metal bumps, and the metal bumps are bonded to exposed portions of the fourth circuit layer 321 through a solder material or a conductive bonding material filled in the second through holes 322a, so that the light emitting device 400 is electrically connected to the fourth circuit layer 321.

As shown in FIG. 3, the light emitting device package structure 10b further includes a light transmissive adhesive layer 500, a protective carrier 600, and a chip protective layer 800. The light transmissive adhesive layer 500 covers the light emitting device 400 and the second insulating layer 322 and is filled between the light emitting device 400 and the second insulating layer 322. The protective carrier 600 is disposed over the light transmissive adhesive layer 500. The chip protective layer 800 covers the chip 200 and is filled in a gap between the chip 200 and the substrate 140. Therefore, the chip protective layer 800 can protect the bonding of the metal bumps of the chip 200 to the second circuit layer 120, thereby preventing occurrence of peeling. On the other hand, the chip protective layer 800 can also block moisture and avoid oxidation of the metal bumps, the solder material, and the second circuit layer 120. It should be noted that the manner in which the light emitting device 400 is disposed over the redistribution structure 300, and the material or type of the substrate 140, the conductive connector C2, the first insulating layer 313, the second insulating layer 322, the conductive contact 312, the solder material or the conductive bonding material filled in the second through hole 322a, the light emitting device 400, the light transmissive adhesive layer 500, the protective carrier 600, and the chip protective layer 800 are as described above, and not described again.

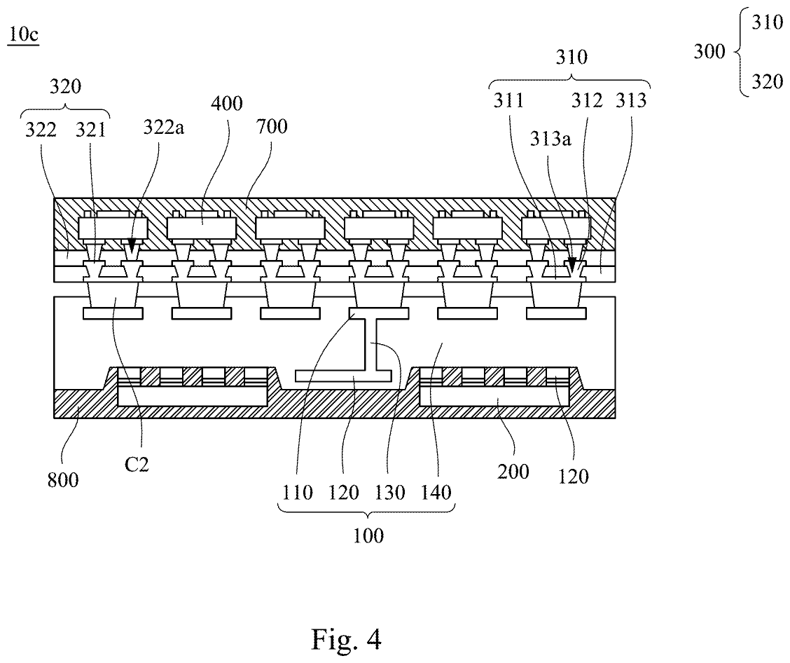

FIG. 4 is a cross-sectional view of a light emitting device package structure 10c according to a fourth embodiment of the present disclosure. The light emitting device package structure 10c of FIG. 4 is similar to that of FIG. 3, and the difference therebetween is that the protective layer 700 of FIG. 4 replaces the light transmissive adhesive layer 500 and the protective carrier 600 of FIG. 3. Specifically, the protective layer 700 covers the light emitting device 400 and the second insulating layer 322 and is filled between the light emitting device 400 and the second insulating layer 322. In some embodiments, the protective layer 700 includes a light transmissive resin. It is noted that as shown in FIG. 4, same or similar elements as those in FIG. 3 are given the same reference numerals, and the description thereof is omitted.

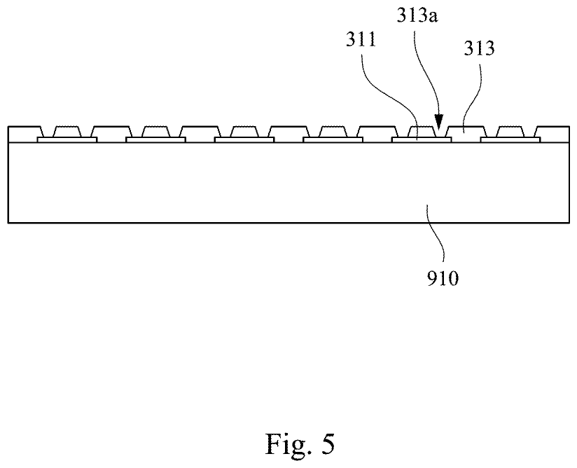

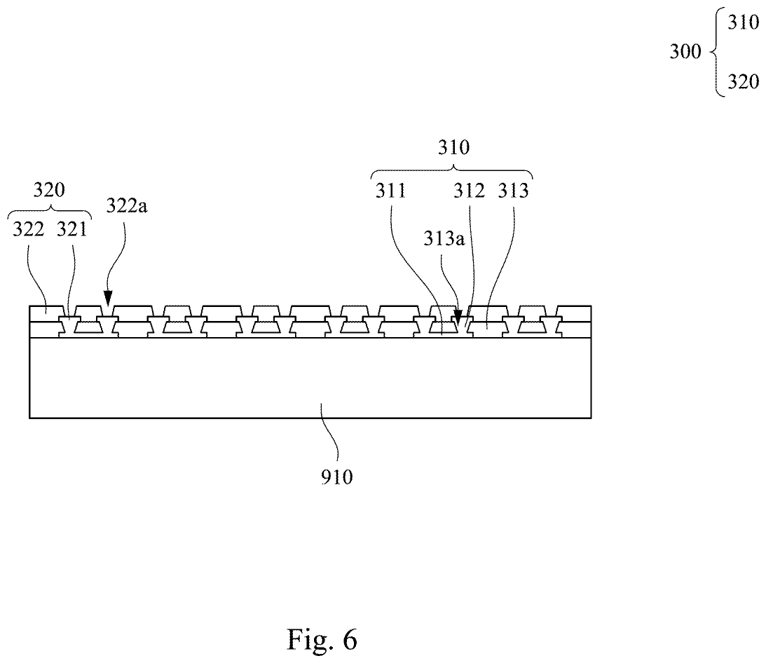

The present disclosure also provides a method of manufacturing a light emitting device package structure. FIGS. 5-6 are cross-sectional views showing stages of a method of forming a redistribution structure according to one embodiment of the present disclosure.

As shown in FIG. 5, a circuit layer 311 is formed over a sacrificial substrate 910. For example, a conductive material is formed over the sacrificial substrate 910, and the conductive material is patterned to form the circuit layer 311. In some embodiments, the method of forming the conductive material includes electroplating, chemical vapor deposition, physical vapor deposition, and the like, but not limited thereto. Next, a first insulating layer 313 is formed covering the circuit layer 311, and the first insulating layer 313 includes a first through hole 313a exposing a portion of the circuit layer 311. For example, a dielectric material is formed over the circuit layer 311, and the dielectric material is patterned to form the first through hole 313a. In some embodiments, the method of forming the dielectric material includes, but not limited to, chemical vapor deposition, physical vapor deposition, and the like. In some embodiments, a method of patterning the conductive material and the dielectric material includes depositing a photoresist over a layer to be patterned, and performing exposure and development to form a patterned photoresist layer. Next, the patterned photoresist layer is used as an etch mask for etching the layer to be patterned. Finally, the patterned photoresist layer is removed. Alternatively, in embodiments where the dielectric material is a photosensitive dielectric material, a patterning process is accomplished by removing a portion of the photosensitive dielectric material using exposure and development.

Subsequently, as shown in FIG. 6, a circuit layer 321 is formed over the first insulating layer 313, and a conductive contact 312 is formed in the first through hole 313a. For example, a conductive material is formed over the first insulating layer 313 and filled in the first through hole 313a. Next, the conductive material is patterned to form the circuit layer 321 and the conductive contact 312. It should be noted that methods of forming the conductive material and patterning the conductive material are described above and not described again. Next, a second insulating layer 322 is formed covering the circuit layer 321 and the first insulating layer 313, and the second insulating layer 322 includes a second through hole 322a exposing a portion of the circuit layer 321. For example, a dielectric material is formed over the circuit layer 321 and the first insulating layer 313, and the dielectric material is patterned to form the second through hole 322a. Accordingly, a redistribution structure 300 is formed over the sacrificial substrate 910. It should be noted that methods of forming the dielectric material and patterning the dielectric material are described above and not described again.

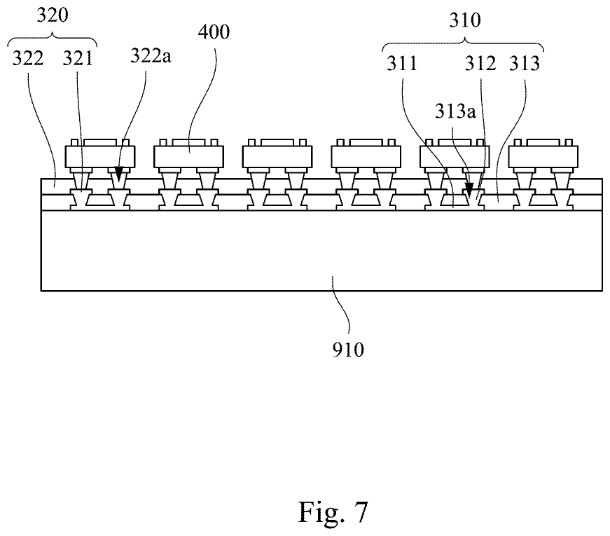

FIGS. 7-9 are cross-sectional views showing stages of a method of forming a light emitting device package structure according to one embodiment of the present disclosure. As shown in FIG. 7, a light emitting device 400 is disposed over the redistribution structure 300 shown in FIG. 6. For example, a solder material or a conductive bonding material is filled in the second through hole 322a, and metal bumps provided on a lower surface of the light emitting device 400 are connected to the solder material or the conductive bonding material. In some embodiments, the manner in which the light emitting device 400 is disposed over the redistribution structure 300 includes a pick and place mode or a mass transfer mode.

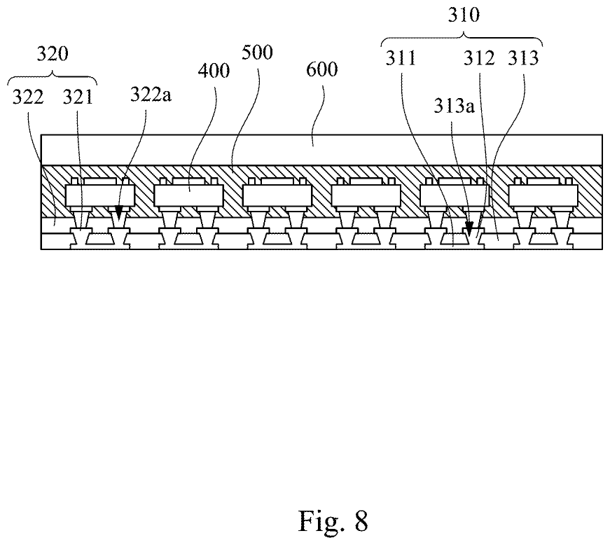

Next, as shown in FIG. 8, a protective carrier 600 is adhered over the light emitting device 400 and the second insulating layer 322. For example, the protective carrier 600 is adhered to the light emitting device 400 and the second insulating layer 322 using an optical adhesive, and thus a light transmissive adhesive layer 500 is formed. Next, a sacrificial substrate 910 is peeled off to expose the circuit layer 311.

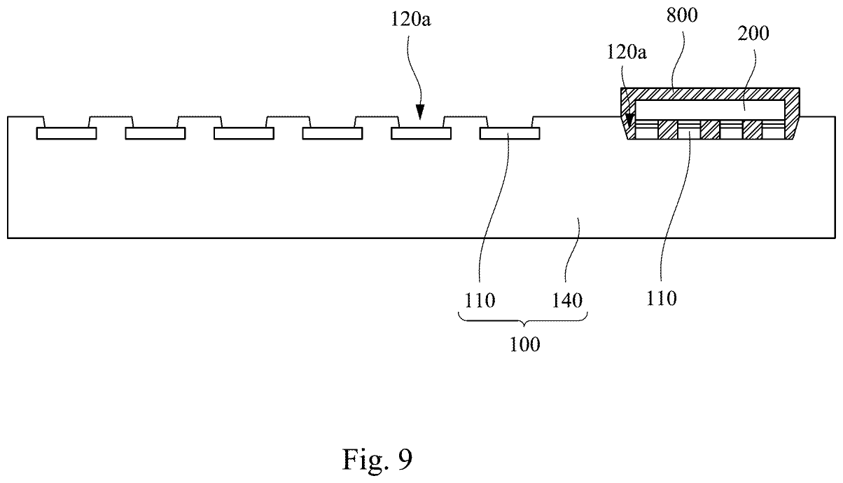

Next, as shown in FIG. 9, a substrate structure 100 including a circuit layer 110 and a substrate 140 is provided. The substrate 140 includes an opening 120a that exposes a portion of the circuit layer 110. Next, a chip 200 is disposed over the substrate structure 100. Specifically, the chip 200 is electrically connected to exposed portions of the circuit layer 110. For example, a plurality of metal bumps (e.g., chip pins) disposed over a lower surface of the chip 200 are bonded to the circuit layer 110 using a solder material or a conductive bonding material.

Next, the structure of FIG. 8 is disposed over the structure of FIG. 9 to form the light emitting device package structure 10 as shown in FIG. 1. Specifically, a conductive connector C2 is formed, and the conductive connector C2 is electrically connected to the circuit layer 311 and the circuit layer 110. For example, in the embodiment where the conductive connector C2 is a solder ball, the solder material is firstly filled in the opening 120a of FIG. 9, such that the solder material is in contact with the circuit layer 110. Next, the exposed portion of the circuit layer 311 of FIG. 8 is connected to the solder material, thereby forming the conductive connector C2.

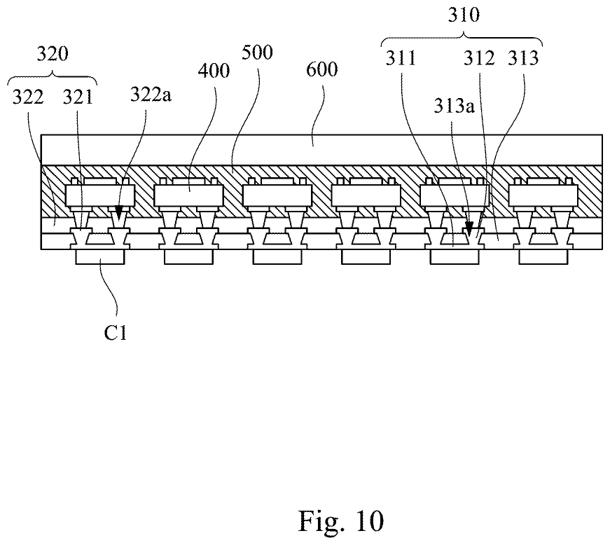

In addition, the present disclosure also provides a method for manufacturing a light emitting device package structure, in which a conductive connector C2 in the light emitting device package structure is a metal pillar. Referring to FIG. 10, FIG. 10 is a cross-sectional view showing a stage of a method of forming a light emitting device package structure according to one embodiment of the present disclosure. FIG. 10 is continued from FIG. 8, a metal block C1 connected to the circuit layer 311 is formed. In some embodiments, the metal block C1 includes a conductive metal such as copper, nickel or silver.

Next, the structure of FIG. 10 is disposed over the structure of FIG. 9 to form the light emitting device package structure 10 as shown in FIG. 1. Specifically, the conductive connector C2 electrically connected to the circuit layer 311 and the circuit layer 110 is formed. For example, the metal block C1 of FIG. 10 is aligned with the opening 120a of FIG. 9. Next, the metal block C1 and the circuit layer 110 are thermally pressed to form the metal pillar connected to the circuit layer 110.

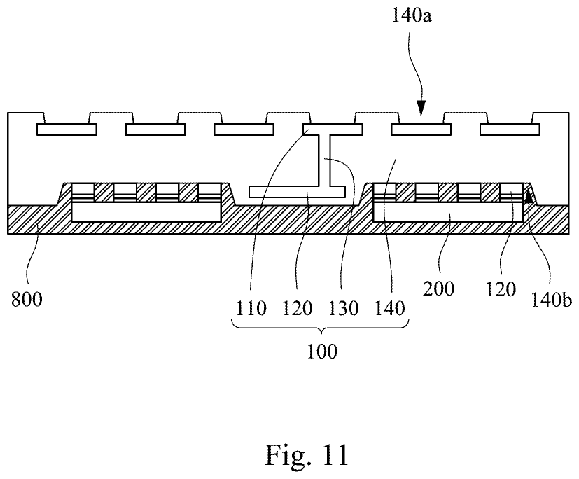

FIG. 11 is a cross-sectional view showing a stage of a method of forming a light emitting device package structure according to one embodiment of the present disclosure. As shown in FIG. 11, a substrate structure 100 including a circuit layer 110, a circuit layer 120, a conductive through hole 130, and a substrate 140 is provided. The substrate 140 includes an opening 140a exposing a portion of the circuit layer 110 and an opening 140b exposing a portion of the circuit layer 120. Next, the chip 200 is disposed beneath the substrate structure 100. Specifically, the chip 200 is electrically connected to exposed portions of the circuit layer 120. For example, a plurality of metal bumps (e.g., chip pins) disposed over a surface of the chip 200 are bonded to the circuit layer 120 using a solder material.

Next, the structure of FIG. 8 or FIG. 10 is disposed over the structure of FIG. 11, thereby forming the light emitting device package structure 10b as shown in FIG. 3. Specifically, a conductive connector C2 electrically to the circuit layer 311 and the circuit layer 110 is formed. It should be noted that the method of forming the conductive connector C2 (e.g., a solder ball or a metal pillar) is described above, and not described again.

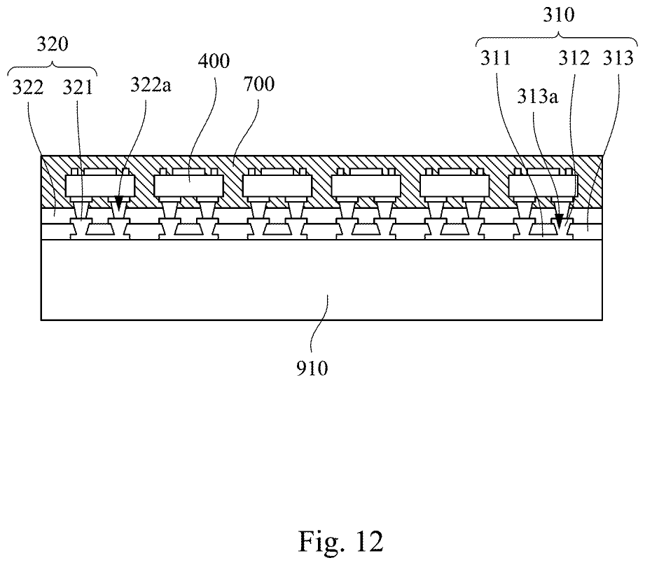

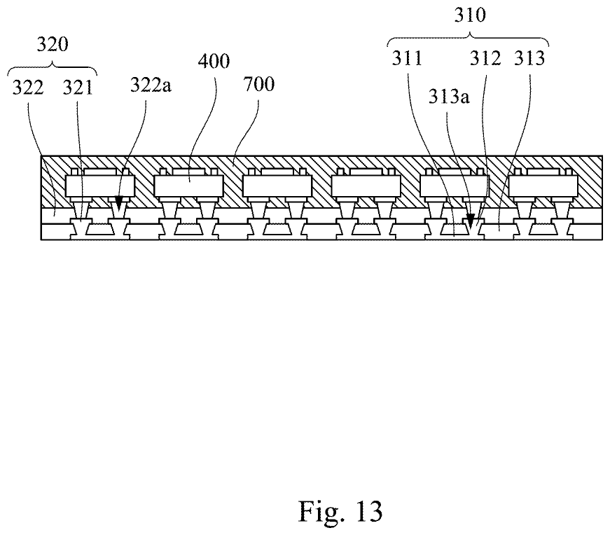

FIGS. 12-13 are cross-sectional views showing stages of a method of forming a light emitting device package structure according to one embodiment of the present disclosure. FIG. 12 is continued from FIG. 7, and a protective layer 700 is formed covering the light emitting device 400 and the second insulating layer 322, and is filled between the light emitting device 400 and the second insulating layer 322. For example, the protective layer 700 is formed using coating, molding, or pressing technique.

Next, as shown in FIG. 13, a sacrificial substrate 910 is peeled off to expose the circuit layer 311.

Next, the structure of FIG. 13 is disposed over the structure of FIG. 9 or FIG. 11 to form the light emitting device package structure 10a or 10c as shown in FIG. 2 or FIG. 4. Specifically, the solder ball electrically connected to the circuit layer 311 and the circuit layer 110 and acted as the conductive connector C2 is formed. The method of forming the solder ball is described above and not described again.

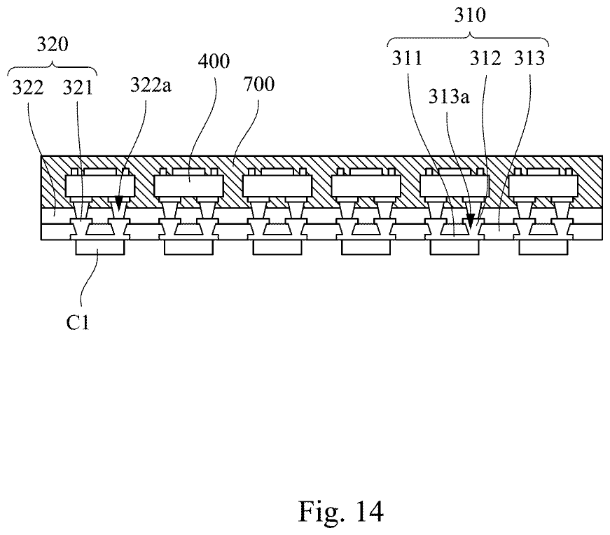

Referring to FIG. 14, FIG. 14 is a cross-sectional view showing a stage of a method of forming a light emitting device package structure according to one embodiment of the present disclosure. FIG. 14 is continued from FIG. 13, and a metal block C1 connected to the circuit layer 311 is formed. In some embodiments, the metal block C1 includes a conductive metal such as copper, nickel or silver.

Next, the structure of FIG. 14 is disposed over the structure of FIG. 9 or FIG. 11 to form the light emitting device package structure 10a or 10c as shown in FIG. 2 or FIG. 4. Specifically, a metal pillar electrically connected to the circuit layer 311 and the circuit layer 110 and acted as the conductive connector C2 is formed. The method of forming the metal pillar is described above, and not described again.

It may be seen from the above embodiments of the present disclosure that in the light emitting device package structure disclosed herein, the light emitting device and the chip are electrically connected using the redistribution structure, instead of the conventional film flip-chip packaging technology. Therefore, the problems that the portion where the flexible circuit board is in contact with the substrate easily peels off or breaks, and the wires on the flexible circuit board are also prone to break and the like when the film flip chip packaging technique is employed are avoided. In addition, it is not necessary to reserve a portion of the substrate to which the flexible circuit board is connected, so that the frame region of the display device may be effectively reduced. On the other hand, since the circuit layer in the redistribution structure has a very small line width and line spacing, the effect of thinning the light emitting device package structure can be achieved.

While the invention has been disclosed above in the embodiments, other embodiments are possible. Therefore, the spirit and scope of the claims are not limited to the description contained in the embodiments herein.

It is apparent to those skilled in the art that various modifications and changes may be made without departing from the spirit and scope of the invention, and the scope of the present disclosure is defined by the scope of the appended claims.

What is claimed is:

1. A light emitting device package structure, comprising:
a substrate structure comprising a substrate and a first circuit layer, wherein the substrate has a first surface, and the first circuit layer is disposed over the first surface;
a chip disposed over the substrate structure and electrically connected to the first circuit layer;
a conductive connector disposed over the substrate structure and electrically connected to the first circuit layer;
a redistribution structure disposed over the conductive connector, the redistribution structure comprising a first redistribution layer and a second redistribution layer disposed over the first redistribution layer, wherein the first redistribution layer comprises a second circuit layer electrically connected to the first circuit layer and a conductive contact in contact with the second circuit layer, and the second redistribution layer comprises a third circuit layer in contact with the conductive contact; and
a light emitting device disposed over the redistribution structure and electrically connected to the third circuit layer.

2. The light emitting device package structure of claim 1, further comprising a protective carrier disclosed over the light emitting device.

3. The light emitting device package structure of claim 1, further comprising a protective layer covering the light emitting device and the second redistribution layer and filled between the light emitting device and the second redistribution layer.

4. A light emitting device package structure, comprising:
a substrate structure comprising a substrate, a first circuit layer, a second circuit layer and a conductive through hole, wherein the substrate has a first surface and a second surface opposite to the first surface, and the first circuit layer is disposed over the first surface, and the second circuit layer is disposed over the second surface, and the first circuit layer is electrically connected to the second circuit layer through the conductive through hole;
a chip disposed at a side of the second surface and electrically connected to the second circuit layer;
a conductive connector disposed over the substrate structure and electrically connected to the first circuit layer;
a redistribution structure disposed over the conductive connector, the redistribution structure comprising a first redistribution layer and a second redistribution layer disposed over the first redistribution layer, wherein the first redistribution layer comprises a third circuit layer electrically connected to the first circuit layer and a conductive contact in contact with the third circuit layer, and the second redistribution layer comprises a fourth circuit layer in contact with the conductive contact; and
a light emitting device disposed over the redistribution structure and electrically connected to the fourth circuit layer.

5. The light emitting device package structure of claim 4, further comprising a protective carrier disclosed over the light emitting device.

6. The light emitting device package structure of claim 4, further comprising a protective layer covering the light emitting device and the second redistribution layer and filled between the light emitting device and the second redistribution layer.

7. A method of manufacturing a light emitting device package structure, comprising:
(i) providing a substrate structure, wherein the substrate structure comprises a first circuit layer;
(ii) disposing a chip over the substrate structure, wherein the chip is electrically connected to the first circuit layer;
(iii) forming a redistribution structure over the substrate structure, wherein the redistribution structure comprises a first redistribution layer and a second redistribution layer disposed over the first redistribution layer, and the first redistribution layer comprises a second circuit layer electrically connected to the first circuit layer through a conductive connector and a conductive contact in contact with the second circuit layer, and the second redistribution layer comprises a third circuit layer in contact with the conductive contact; and
(iv) disposing a light emitting device over the redistribution structure, wherein the light emitting device is electrically connected to the third circuit layer.

8. The method of manufacturing the light emitting device package structure of claim 7, after the step (iv), further comprising:
(v) forming a protective carrier over the light emitting device; or
(vi) forming a protective layer covering the light emitting device and the second redistribution layer and filled between the light emitting device and the second redistribution layer.

9. A method of manufacturing a light emitting device package structure, comprising:
(a) providing a substrate structure, wherein the substrate structure comprises a first circuit layer, a second circuit layer and a conductive through hole, and the first circuit layer is electrically connected to the second circuit layer through the conductive through hole;
(b) disposing a chip beneath the substrate structure, wherein the chip is electrically connected to the second circuit layer;
(c) forming a redistribution structure over the substrate structure, wherein the redistribution structure comprises a first redistribution layer and a second redistribution layer disposed over the first redistribution layer, and the first redistribution layer comprises a third circuit layer electrically connected to the first circuit layer through a conductive connector and a conductive contact in contact with the third circuit layer, and the second redistribution layer comprises a fourth circuit layer in contact with the conductive contact; and
(d) disposing a light emitting device over the redistribution structure, wherein the light emitting device is electrically connected to the fourth circuit layer.

10. The method of manufacturing the light emitting device package structure of claim 9, after the step (d), further comprising:
(e) forming a protective carrier over the light emitting device; or
(f) forming a protective layer covering the light emitting device and the second redistribution layer and filled between the light emitting device and the second redistribution layer.
